(19) United States
(12) Patent Application Publication
(10) Pub. No.: US 2023/0189545 A1
(43) Pub. Date: Jun. 15, 2023

(54) DISPLAY DEVICE AND ELECTRONIC APPARATUS

(71) Applicant: SONY SEMICONDUCTOR SOLUTIONS CORPORATION, KANAGAWA (JP)

(72) Inventors: HIDEYUKI TANAKA, KANAGAWA (JP); TATSUYA KANO, KANAGAWA (JP)

(21) Appl. No.: 17/927,140

(22) PCT Filed: May 13, 2021
(86) PCT No.: PCT/JP2021/018242

§ 371 Date: Nov. 22, 2022

(30) Foreign Application Priority Data
Jun. 2, 2020 (JP) 2020-096480

(51) Int. Cl. H10K 50/17

(52) U.S. Cl. CPC H10K 50/171

(57) ABSTRACT

A display device includes a first electrode, a second electrode, a light emitting layer disposed between the first electrode and the second electrode, and an auxiliary electrode connected to the second electrode. The auxiliary electrode includes a first auxiliary electrode and a second auxiliary electrode disposed between the first auxiliary electrode and the second electrode. The second auxiliary electrode contains at least one of an alkaline earth metal element and a lanthanoid element.

### TECHNICAL FIELD

The present disclosure relates to a display device and an electronic apparatus including the display device.

### BACKGROUND ART

As a display device such as an organic electroluminescence (EL) display device, a display device including a first electrode, a second electrode, a light emitting layer disposed between the first electrode and the second electrode, and an auxiliary electrode connected to the second electrode is known.

In the display device having the above-described structure, when a contact resistance between the second electrode and the auxiliary electrode increases, a drive voltage increases. For this reason, conventionally, a technique for reducing a drive voltage of a display device has been studied. For example, Patent Document 1 discloses that by forming a barrier layer 8 on a surface layer of an extraction electrode 5, generation of an alteration layer 7 that increases a contact resistance is prevented, and an organic electroluminescence display device that can be driven at a relatively low voltage is obtained. Furthermore, Patent Document 1 discloses, as a metal material of the barrier layer 8, Au, Pt, Pd, W, Mo, and the like having excellent alteration resistance.

### CITATION LIST

### Patent Document

### Patent Document 1: Japanese Patent Application Laid-Open No. 2001-351778

### SUMMARY OF THE INVENTION

### Problems to be Solved by the Invention

As described above, in recent years, it is desired to reduce a drive voltage of a display device.

An object of the present disclosure is to provide a display device capable of reducing a drive voltage and an electronic apparatus including the display device.

### Solutions to Problems

In order to solve the above-described problem, a first disclosure is a display device including:

a first electrode;

a second electrode;

a light emitting layer disposed between the first electrode and the second electrode; and

an auxiliary electrode connected to the second electrode, in which the auxiliary electrode includes:
a first auxiliary electrode; and a second auxiliary electrode disposed between the first auxiliary electrode and the second electrode, and the second auxiliary electrode contains at least one of an alkaline earth metal element and a lanthanoid element.

A second disclosure is an electronic apparatus including the display device of the first disclosure.

### BRIEF DESCRIPTION OF DRAWINGS

FIG. 1 is a plan view illustrating an example of a configuration of an organic EL display device according to a first embodiment of the present disclosure.

FIG. 2 is a cross-sectional view taken along line II-II in FIG. 1.

FIG. 3 is an enlarged cross-sectional view of an organic layer illustrated in FIG. 2.

FIG. 4 is a diagram illustrating examples of an energy diagram of an MIM structure when various materials are used as materials of an auxiliary electrode.

FIG. 5 is a diagram illustrating a first example of the energy diagram of the MIM structure.

FIG. 6 is a diagram illustrating a second example of the energy diagram of the MIM structure.

FIG. 7 is a cross-sectional view illustrating an example of a configuration of an organic EL display device according to a second embodiment of the present disclosure.

FIG. 8A is a front view illustrating an example of an external appearance of a digital still camera. FIG. 8B is a back view illustrating an example of the external appearance of the digital still camera.

FIG. 9 is a perspective view illustrating an example of an external appearance of a head mounted display.

FIG. 10 is a perspective view illustrating an example of an external appearance of a television apparatus.

### MODE FOR CARRYING OUT THE INVENTION

Embodiments of the present disclosure will be described in the following order. Note that in all the drawings of the following embodiments, the same or corresponding parts are denoted by the same reference numerals.

1 First embodiment
1.1 Configuration of display device
1.2 Method for manufacturing display device
1.3 Action and effect

2 Second embodiment
2.1 Configuration of display device
2.2 Action and effect

3 Modification Example

4 Application Example

### 1 First Embodiment

### [1.1 Configuration of Display Device]

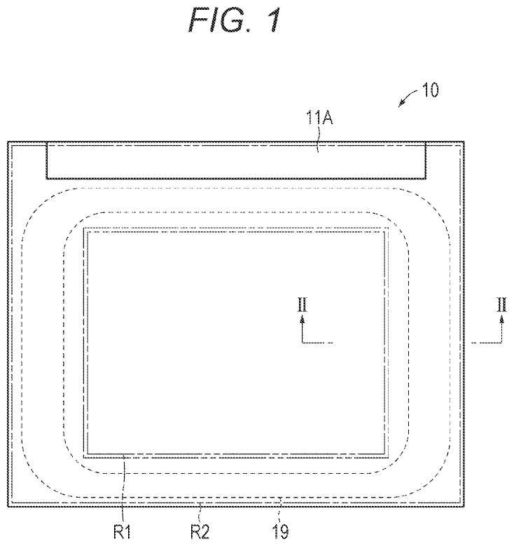

FIG. 1 is a plan view illustrating an example of a configuration of an organic EL display device 10 (hereinafter, simply referred to as “display device 10”) according to a first embodiment of the present disclosure. The display device 10 includes an effective display region R1 and a peripheral region R2 formed around the effective display region R1.

In the effective display region R1, a plurality of subpixels (not illustrated) is arranged in a matrix. The plurality of subpixels includes a plurality of red subpixels that displays red, a plurality of green subpixels that displays green, and a plurality of blue subpixels that displays blue. These three-color subpixels are arranged in a prescribed pattern. One pixel includes three subpixels of red, green, and blue. In the peripheral region R2, a pad portion 11A, a driver for video display (not illustrated), and the like are disposed.

The display device 10 is, for example, a microdisplay in which self-light emitting elements such as OLEDs or Micro-OLEDs are formed in an array. The display device 10 is suitably used for a display device for virtual reality (VR), mixed reality (MR), or augmented reality (AR), an electronic viewfinder (EVF), a small projector, or the like.

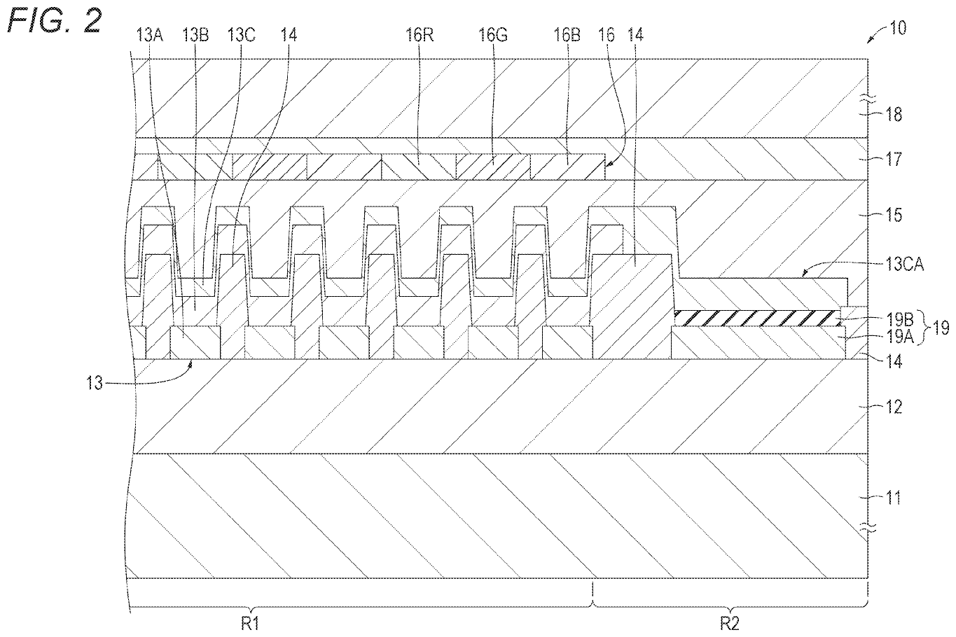

FIG. 2 is a cross-sectional view taken along line II-II in FIG. 1. The display device 10 is a top emission type display device, and includes a substrate (first substrate) 11, an insulating layer 12, a plurality of light emitting elements 13, an insulating layer 14, a protective layer 15, a color filter 16, a filling resin layer 17, a counter substrate (second substrate) 18, and an auxiliary electrode 19. Note that the counter substrate 18 side is a top side, and the substrate 11 side is a bottom side.

### (Substrate)

On the substrate 11, a drive circuit including a sampling transistor and a driving transistor that control driving of the plurality of light emitting elements 13, a power supply circuit that supplies power to the plurality of light emitting elements 13, and the like may be disposed.

The substrate 11 may be constituted by, for example, a glass substrate or a resin substrate having a small content of moisture and a low oxygen transmissive property, or may be constituted by a semiconductor substrate that easily forms a transistor or the like. The glass substrate contains, for example, at least one of high strain point glass, soda glass, borosilicate glass, forsterite, lead glass, and quartz glass. The resin substrate contains, for example, at least one polymer resin of polymethyl methacrylate, polyvinyl alcohol, polyvinyl phenol, polyether sulfone, polyimide, polycarbonate, polyethylene terephthalate, and polyethylene naphthalate. The semiconductor substrate contains amorphous silicon, polycrystalline silicon (polysilicon), or single crystal silicon.

### (Light Emitting Element)

The plurality of light emitting elements 13 is disposed on the insulating layer 12. The plurality of light emitting elements 13 is arranged in a matrix on one main surface of the substrate 11. The light emitting element 13 can emit white light. The light emitting element 13 is, for example, a white OLED or a white Micro-OLED (MOLED). As a coloring method in the display device 10, a method using the light emitting element 13 and the color filter 16 is used. However, the coloring method is not limited thereto, and an RGB separately coloring method or the like may be used. Furthermore, a monochromatic filter may be used instead of the color filter 16.

The light emitting element 13 includes a first electrode 13A, an organic layer 13B, and a second electrode 13C. The first electrode 13A, the organic layer 13B, and the second electrode 13C are laminated in this order from the substrate 11 side toward the counter substrate 18.

### (First Electrode)

The first electrode 13A is disposed on the insulating layer 12. The first electrodes 13A are electrically separated from each other for each subpixel. The first electrode 13A is an anode. The first electrode 13A also functions as a reflecting layer, and is preferably made of a material having a reflectance as high as possible and a large work function in order to enhance light emission efficiency.

The first electrode 13A is constituted by at least one of a metal layer and a metal oxide layer. More specifically, the second electrode 13C is constituted by a single layer film of a metal layer or a metal oxide layer, or a laminated film of a metal layer and a metal oxide layer. In a case where the first electrode 13A is constituted by a laminated film, the metal oxide layer may be disposed on the organic layer 13B side, or the metal layer may be disposed on the organic layer 13B side. However, the metal oxide layer is preferably disposed on the organic layer 13B side from a viewpoint of making a layer having a high work function adjacent to the organic layer 13B.

The metal layer contains, for example, at least one metal element of chromium (Cr), gold (Au), platinum (Pt), nickel (Ni), copper (Cu), molybdenum (Mo), titanium (Ti), tantalum (Ta), aluminum (Al), magnesium (Mg), iron (Fe), tungsten (W), and silver (Ag). The metal layer may contain the above-described at least one metal element as a constituent element of an alloy. Specific examples of the alloy include an aluminum alloy and a silver alloy. Specific examples of the aluminum alloy include AlNd and AlCu.

The metal oxide layer contains, for example, at least one of a mixture of indium oxide and tin oxide (ITO), a mixture of indium oxide and zinc oxide (IZO), and titanium oxide (TiO).

### (Second Electrode)

The second electrode 13C is disposed so as to face the first electrode 13A. The second electrode 13C is disposed as an electrode common to all subpixels in the effective display region R1. The second electrode 13C is a cathode. The second electrode 13C is a transparent electrode having a transmissive property for light generated in the organic layer 13B. Here, the transparent electrode also includes a semi-transmissive reflecting layer. The second electrode 13C is preferably made of a material having a transmissive property as high as possible and a small work function in order to enhance light emission efficiency.

The second electrode 13C is constituted by at least one of a metal layer and a metal oxide layer. More specifically, the second electrode 13C is constituted by a single layer film of a metal layer or a metal oxide layer, or a laminated film of a metal layer and a metal oxide layer. In a case where the second electrode 13C is constituted by a laminated film, the metal layer may be disposed on the organic layer 13B side and the second auxiliary electrode 19B side, or the metal oxide layer may be disposed on the organic layer 13B side and the second auxiliary electrode 19B side. However, the metal layer is preferably disposed on the organic layer 13B side and the second auxiliary electrode 19B side from a viewpoint of making a layer having a low work function adjacent to the organic layer 13B.

The metal layer contains, for example, at least one metal element of magnesium (Mg), aluminum (Al), silver (Ag), calcium (Ca), and sodium (Na). The metal layer may contain the above-described at least one metal element as a constituent element of an alloy. Specific examples of the alloy include an MgAg alloy, an MgAl alloy, and an AlLi alloy. The metal oxide contains, for example, at least one of a mixture of indium oxide and tin oxide (ITO), a mixture of indium oxide and zinc oxide (IZO), and zinc oxide (ZnO).

### (Organic Layer)

The organic layer 13B is disposed between the first electrode 13A and the second electrode 13C. The organic layer 13B is disposed as an organic layer common to all subpixels in the effective display region R1. The organic layer 13B can emit white light.

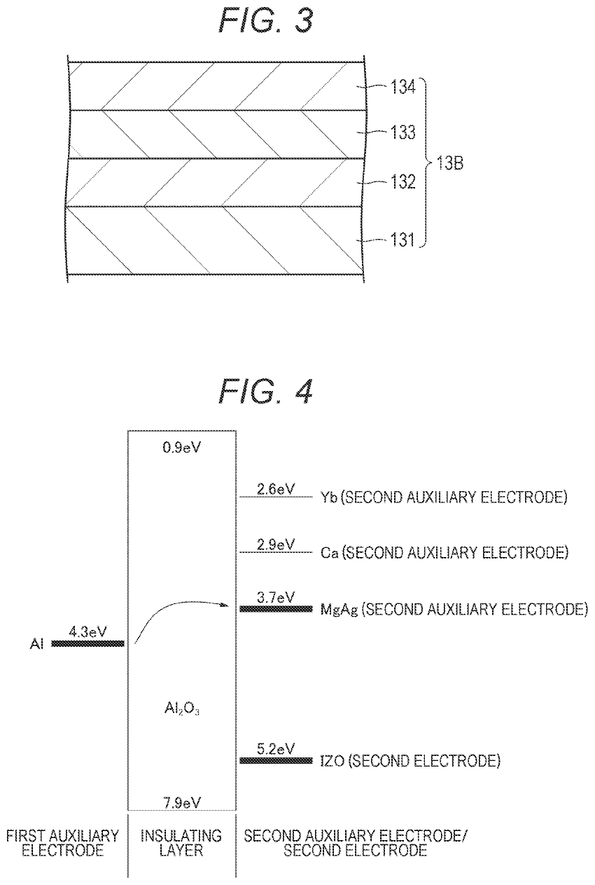

FIG. 3 is an enlarged cross-sectional view of the organic layer 13B illustrated in FIG. 2. The organic layer 13B has a configuration in which a hole injection layer 131, a hole transport layer 132, a light emitting layer 133, and an electron transport layer 134 are laminated in this order from the first electrode 13A toward the second electrode 13C. Note that the configuration of the organic layer 13B is not limited thereto, and the layers other than the light emitting layer 133 are disposed as necessary.

The hole injection layer 131 is disposed for enhancing hole injection efficiency into the light emitting layer 133 and is a buffer layer for suppressing leakage. The hole transport layer 132 is disposed for increasing hole transport efficiency to the light emitting layer 133. When an electric field is applied to the light emitting layer 133, recombination of electrons and holes occurs to generate light. The light emitting layer 133 is an organic light emitting layer containing an organic light emitting material. The electron transport layer 134 is disposed for enhancing electron transport efficiency to the light emitting layer 133. An electron injection layer (not illustrated) containing LiF or the like may be disposed between the electron transport layer 134 and the second electrode 13C. This electron injection layer is disposed for enhancing electron injection efficiency.

### (Auxiliary Electrode)

The auxiliary electrode 19 is connected to a peripheral edge portion 13CA of the second electrode 13C. The auxiliary electrode 19 is disposed on the insulating layer 12 and in the peripheral region R2. As illustrated in FIG. 1, the auxiliary electrode 19 has a closed loop shape so as to surround a peripheral edge of the effective display region R1. The auxiliary electrode 19 includes a first auxiliary electrode 19A and a second auxiliary electrode 19B. The first auxiliary electrode 19A is disposed on the insulating layer 12. The second auxiliary electrode 19B is disposed between the first auxiliary electrode 19A and the second electrode 13C.

The first auxiliary electrode 19A is connected to the peripheral edge portion 13CA of the second electrode 13C via the second auxiliary electrode 19B. The first auxiliary electrode 19A is constituted by at least one of a metal layer and a metal oxide layer. More specifically, the first auxiliary electrode 19A is constituted by a single layer film of a metal layer or a metal oxide layer, or a laminated film of a metal layer and a metal oxide layer. In a case where the first auxiliary electrode 19A is constituted by a laminated film, the metal oxide layer may be disposed on the second auxiliary electrode 19B side, or the metal layer may be disposed on the second auxiliary electrode 19B side.

The first auxiliary electrode 19A may have the same configuration as the first electrode 13A. The metal layer and the metal oxide layer of the first auxiliary electrode 19A may have the same configuration as the metal layer and the metal oxide layer of the first electrode 13A, respectively.

In a case where the first auxiliary electrode 19A is constituted by a metal layer, or in a case where the first auxiliary electrode 19A is constituted by a laminated film including a metal layer on the second auxiliary electrode 19B side, an insulating layer may be disposed between the metal layer and the second auxiliary electrode 19B. The above-described insulating layer may be formed, for example, by oxidizing a surface of the first auxiliary electrode 19A at the time of surface treatment (for example, plasma treatment) of the first auxiliary electrode 19A or film formation of the second auxiliary electrode 19B. The above-described insulating layer may be a metal oxide layer containing a metal element similar to that in the above-described metal layer. The auxiliary electrode 19 may be able to inject electrons from the first auxiliary electrode 19A to the second auxiliary electrode 19B via the above-described insulating layer due to a tunnel effect.

An average thickness of the above-described insulating layer is preferably 3 nm or less from a viewpoint of reducing a drive voltage. The average thickness of the above-described insulating layer is determined as follows. First, a cross section of the display device 10 is cut out by focused ion beam (FIB) processing or the like to prepare a thin piece. Subsequently, the prepared thin piece is observed with a transmission electron microscope (TEM), and one cross-sectional TEM image is acquired. At this time, acceleration voltage is set to 80 kV. Next, in the acquired one cross-sectional TEM image, the thickness of the above-described insulating layer is measured at ten or more points. At this time, the measurement points are randomly selected. Thereafter, the film thicknesses of the above-described insulating layer measured at ten or more points are simply averaged (arithmetically averaged) to determine the average thickness of the above-described insulating layer.

The second auxiliary electrode 19B may have an electron injection property. The second auxiliary electrode 19B is a connection improving layer for improving connectivity between the first auxiliary electrode 19A and the second electrode 13C. Specifically, the second auxiliary electrode 19B is a layer for improving an electron injection property from the first auxiliary electrode 19A to the second electrode 13C. A work function of the second auxiliary electrode 19B is preferably smaller than a work function of the first auxiliary electrode 19A from a viewpoint of reducing a drive voltage.

The second auxiliary electrode 19B is made of a material that can be formed into a film by low temperature vapor deposition. Specifically, the second auxiliary electrode 19B contains at least one of an alkaline earth metal element and a lanthanoid element. The second auxiliary electrode 19B may contain the above-described at least one element as a constituent element of an alloy. Since the second auxiliary electrode 19B is made of a material that can be formed into a film by low temperature deposition, damage to a surface of the first auxiliary electrode 19A can be suppressed at the time of film formation of the second auxiliary electrode 19B. Note that even if a surface of the second auxiliary electrode 19B is oxidized at the time of film formation of the second electrode 13C, bonding between the second auxiliary electrode 19B and the second electrode 13C is similar to metal-metal bonding. Therefore, even if the surface of the second auxiliary electrode 19B is oxidized, there is no significant influence on connectivity between the second auxiliary electrode 19B and the second electrode 13C. That is, there is no significant influence on a drive voltage.

The alkaline earth metal element includes, for example, at least one selected from the group consisting of beryllium (Be), magnesium (Mg), calcium (Ca), strontium (Sr), barium (Ba), and radium (Ra). The lanthanoid element includes, for example, at least one selected from the group consisting of lanthanum (La), cerium (Ce), praseodymium (Pr), neodymium (Nd), promethium (Pm), samarium (Sm), europium (Eu), gadolinium (Gd), terbium (Tb), dysprosium (Dy), holmium (Ho), erbium (Er), thulium (Tm), ytterbium (Yb), and lutetium (Lu). Specifically, the second auxiliary electrode 19B contains, for example, MgAg, MgAl, Ca, CaLiF, Ba, Sr, or Yb.

Hereinafter, a configuration example in which the first auxiliary electrode 19A is constituted by a metal layer will be described. In a case where the first auxiliary electrode 19A is constituted by a metal layer, a surface of the first auxiliary electrode 19A (a surface on the second auxiliary electrode 19B side) is oxidized in a manufacturing process, and an insulating layer is easily formed.

In a case where the insulating layer is formed on the surface of the first auxiliary electrode 19A, electrons are injected from the first auxiliary electrode 19A to the second auxiliary electrode 19B due to a tunnel effect when a drive voltage is applied. That is, a tunnel current flows between the first auxiliary electrode 19A and the second auxiliary electrode 19B.

Table 1 illustrates examples of materials and work functions of the first auxiliary electrode 19A and the second auxiliary electrode 19B.

TABLE 1

| MIM device structure | | | | | |
|---|---|---|---|---|---|
| Material | | Material | | | |
| of first | Insulating | of second | Electronic property | | |
| auxiliary | layer | auxiliary | W1 | W2 | ΔW (=W1 − |
| electrode | Material | electrode | [eV] | [eV] | W2) [eV] |
| Al | Al₂O₃ | MgAg | 4.3 | 3.7 | 0.6 |
| | | IZO | | 5.2 | −0.9 |
| | | Ca | | 2.9 | 1.4 |
| | | Yb | | 2.6 | 1.7 |

Here, W1, W2, and ΔW are as follows.

W1: work function of first auxiliary electrode 19A

W2: work function of second auxiliary electrode 19B

ΔW: difference between work function W1 of first auxiliary electrode 19A and work function W2 of second auxiliary electrode 19B (W1−W2)

FIG. 4 is a diagram illustrating examples of an energy diagram of a metal-insulator-metal (MIM) structure using the materials illustrated in Table 1. Note that this diagram illustrates a state where the first auxiliary electrode 19A, the insulating layer, and the second auxiliary electrode 19B are not bonded to each other. As illustrated in Table 1 and FIG. 4, the difference ΔW between work functions varies depending on a combination of materials of the first auxiliary electrode 19A and the second auxiliary electrode 19B. There is a correlation between the difference ΔW between work functions (=W1−W2) and a drive voltage Vth, and the above-described correlation can be described with an electron injection model by MIM tunneling.

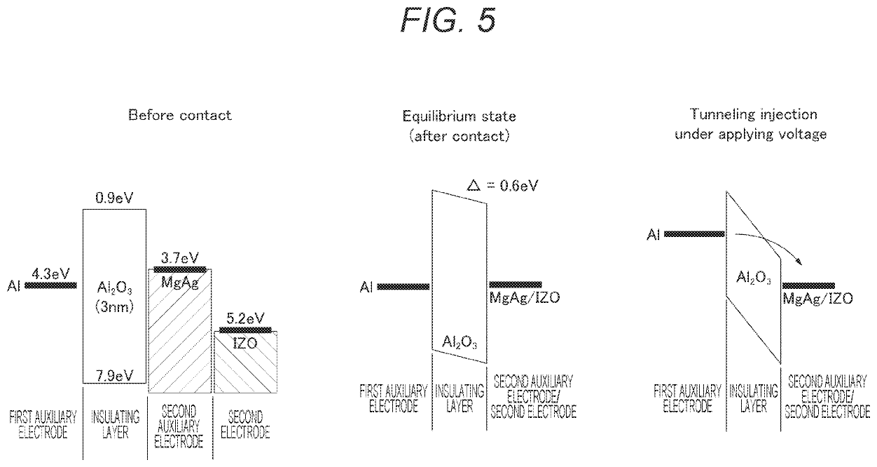

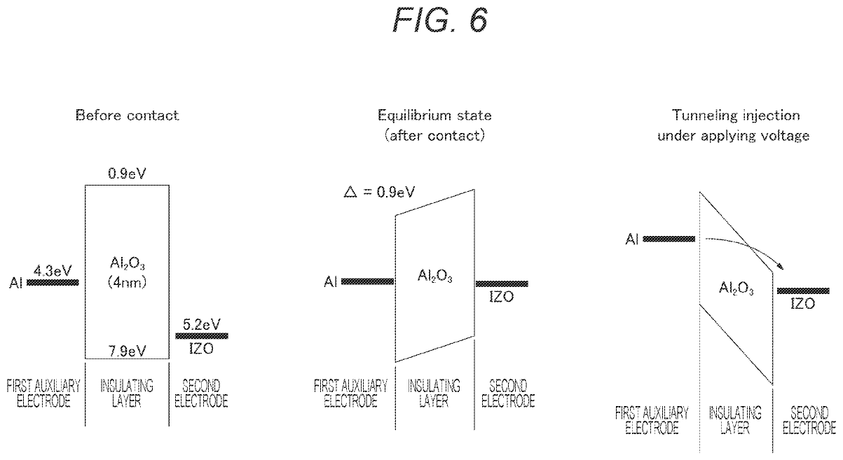

Hereinafter, a specific example of the above-described correlation will be described with the electron injection model by MIM tunneling with reference to FIGS. 5 and 6.

FIG. 5 is a diagram illustrating a first example of the energy diagram of the MIM structure. In the first example, an example will be described in which the first auxiliary electrode 19A, the insulating layer, the second auxiliary electrode 19B, and the second electrode 13C are made of Al, Al₂O₃, MgAg, and IZO, respectively. In a state where the first auxiliary electrode 19A, the insulating layer, and the second auxiliary electrode 19B are bonded to each other, a potential barrier of the insulating layer is high on the first auxiliary electrode 19A side and low on the second auxiliary electrode 19B side. Therefore, in the first example, electrons tunnel from the first auxiliary electrode 19A to the second auxiliary electrode 19B even when a low drive voltage Vth is applied.

FIG. 6 is a diagram illustrating a second example of the energy diagram of the MIM structure. In the second example, an example will be described in which formation of the second auxiliary electrode 19B is omitted, and the first auxiliary electrode 19A, the insulating layer, and the second electrode 13C are made of Al, Al₂O₃, and IZO, respectively. In a state where the first auxiliary electrode 19A, the insulating layer, and the second auxiliary electrode 19B are bonded to each other, a potential barrier of the insulating layer is low on the first auxiliary electrode 19A side and high on the second auxiliary electrode 19B side. Furthermore, when the second electrode 13C is made of IZO, thermal energy at the time of film formation of the second electrode 13C is high, and oxidation of a surface of the first auxiliary electrode 19A easily proceeds at the time of film formation of the second electrode 13C. Therefore, the width of the barrier of the insulating layer tends to be larger than the width of the barrier of the insulating layer in the above-described first example (see FIG. 5). Therefore, in the second example, unless a high drive voltage Vth is applied, electrons do not tunnel from the first auxiliary electrode 19A to the second auxiliary electrode 19B.

In the above-described configuration example, the example has been described in which the first auxiliary electrode 19A is constituted by a single layer film of a metal layer, but a case where the first auxiliary electrode 19A is constituted by a laminated film including a metal layer on the second auxiliary electrode 19B side is also similar to the above-described configuration example.

### (Insulating Layer)

In the effective display region R1, the insulating layer 14 electrically separates the first electrodes 13A from each other for each light emitting element 13 (that is, for each subpixel). The insulating layer 14 has a plurality of first openings, and an upper surface of the first electrode 13A (a surface facing the second electrode 13C) is exposed from each of the first openings. The insulating layer 14 may cover a portion extending from a peripheral edge portion of the upper surface of the first electrode 13A to a side surface (end surface) of the first electrode 13A.

The insulating layer 14 separates each light emitting element 13 disposed on a peripheral edge of the effective display region R1 from the auxiliary electrode 19 disposed in the peripheral region R2. The insulating layer 14 has a second opening, and an upper surface of the auxiliary electrode 19 (a surface facing the second electrode 13C) is exposed from the second opening. The insulating layer 14 may cover a portion extending from a peripheral edge portion of the upper surface of the auxiliary electrode 19 to a side surface (end surface) of the auxiliary electrode 19.

The insulating layer 14 is made of, for example, an organic material or an inorganic material. The organic material contains, for example, at least one of polyimide and an acrylic resin. The inorganic material contains, for example, at least one of silicon oxide, silicon nitride, silicon oxynitride, and aluminum oxide.

The insulating layer 12 includes a plurality of contact plugs and the like (not illustrated). The first electrode 13A of each light emitting element 13 is connected to a drive circuit of the substrate 11 via the contact plugs. The first auxiliary electrode 19A is connected to the drive circuit via the contact plugs. As a constituent material of the insulating layer 12, a material similar to that of the above-described insulating layer 14 can be exemplified.

### (Protective Layer)

The protective layer 15 is disposed on the second electrode 12C and covers the light emitting element 13, the peripheral edge portion 13CA of the second electrode 13C, and the like. The protective layer 15 blocks the light emitting element 13 and the peripheral edge portion 13CA of the second electrode 13C from outside air, and suppresses infiltration of moisture into the light emitting element 13 and the auxiliary electrode 19 from an external environment. Furthermore, in a case where the second electrode 13C is constituted by a metal layer, the protective layer 15 may have a function of suppressing oxidation of the metal layer.

The protective layer 15 is made of, for example, an inorganic material having low hygroscopicity. The inorganic material contains, for example, at least one of silicon oxide (SiO), silicon nitride (SiN), silicon oxynitride (SiNO), titanium oxide (TiO), and aluminum oxide (AlO). The protective layer 15 may have a single layer structure, but may have a multilayer structure in a case where the thickness is increased. This is for alleviating an internal stress in the protective layer 15. The protective layer 15 may be made of a polymer resin. The polymer resin contains, for example, at least one of a thermosetting resin and an ultraviolet curable resin.

### (Color Filter)

The color filter 16 is disposed on the protective layer 15. The color filter 16 is, for example, an on chip color filter (OCCF). The color filter 16 includes, for example, a red filter 16R, a green filter 16G, and a blue filter 16B. The red filter 16R, the green filter 16G, and the blue filter 16B are disposed so as to face the light emitting element 13 of a red subpixel, the light emitting element 13 of a green subpixel, and the light emitting element 13 of a blue subpixel, respectively. Therefore, white light emitted from the light emitting element 13 in the red subpixel, white light emitted from the light emitting element 13 in the green subpixel, and white light emitted from the light emitting element 13 in the blue subpixel pass through the above-described red filter 16R, green filter 16G, and blue filter 16B, and red light, green light, and blue light are thereby emitted from a display surface, respectively. Furthermore, a light shielding layer (not illustrated) may be disposed between the color filters 16R, 16G, and 16B of the colors, that is, in a region between subpixels. Note that the color filter 16 is not limited to the on chip color filter, and may be disposed on one main surface of the counter substrate 18.

### (Filling Resin Layer)

The filling resin layer 17 is disposed between the color filter 16 and the counter substrate 18. The filling resin layer 17 has a function as an adhesive layer for bonding the color filter 16 to the counter substrate 18. The filling resin layer 17 contains, for example, at least one of a thermosetting resin and an ultraviolet curable resin.

### (Counter Substrate)

The counter substrate 18 is disposed so as to face the substrate 11. More specifically, the counter substrate 18 is disposed such that one main surface of the counter substrate 18 faces one main surface (surface on which the plurality of light emitting elements 13 is disposed) of the substrate 11. The counter substrate 18 is disposed for sealing the light emitting element 13, the color filter 16, the auxiliary electrode 19, and the like together with the filling resin layer 17. The counter substrate 18 is made of a material such as glass transparent to each color light emitted from the color filter 16.

### [1.2 Method for Manufacturing Display Device]

Hereinafter, a method of manufacturing the display device 10 having the above-described configuration will be described.

First, a drive circuit or the like is formed on one main surface of the substrate 11 using, for example, a thin film forming technique, a photolithography technique, and an etching technique. Next, the insulating layer 12 is formed on the drive circuit or the like by, for example, a CVD method, and then a plurality of contact plugs or the like is formed in the insulating layer 12. Next, a single layer film of a metal layer or a metal oxide layer, or a laminated film of a metal layer and a metal oxide layer is formed on the insulating layer 12 by, for example, a sputtering method, and then the single layer film or the laminated film is patterned using, for example, a photolithography technique and an etching technique, thereby forming the first electrodes 13A separated from each other for each light emitting element 13 (that is, for each pixel) and the first auxiliary electrode 19A.

Next, surfaces of the first electrodes 13A and the first auxiliary electrode 19A are subjected to plasma treatment. In a case where each of the first electrodes 13A and the first auxiliary electrode 19A is a single layer film of a metal layer or a laminated film having a metal layer on a surface thereof, the surfaces of the first electrodes 13A and the first auxiliary electrode 19A may be oxidized by the above-described plasma treatment to form an insulating layer (metal oxide layer).

Next, the insulating layer 14 is formed so as to cover the surfaces of the first electrodes 13A and the first auxiliary electrode 19A by, for example, a CVD method, and then the insulating layer 14 is patterned using a photolithography technique and an etching technique. Next, the second auxiliary electrode 19B is formed on the surface of the first auxiliary electrode 19A or the like by, for example, a vapor deposition method, and then the second auxiliary electrode 19B is patterned using a photolithography technique and an etching technique.

Next, the hole injection layer 131, the hole transport layer 132, the light emitting layer 133, and the electron transport layer 134 are laminated in this order on the first electrodes 13A and the insulating layer 14 by, for example, a vapor deposition method, thereby forming the organic layer 13B. Next, the second electrode 13C is formed on surfaces of the organic layer 13B and the second auxiliary electrode 19B by, for example, a vapor deposition method or a sputtering method. Therefore, the plurality of light emitting elements 13 is formed on one main surface of the substrate 11, and the peripheral edge portion 13CA of the second electrode 13C is bonded to the second auxiliary electrode 19B.

Next, the protective layer 15 is formed on the second electrode 13C by, for example, a vapor deposition method or a CVD method, and then the color filter 16 is formed on the protective layer 15 by, for example, photolithography. Note that in order to flatten a step difference of the protective layer 15 and a step difference due to a film thickness difference of the color filter 16 itself, a flattening layer may be formed on the color filter 16, under the color filter 16, or on and under the color filter 16. Next, the color filter 16 is covered with the filling resin layer 17 by, for example, a one drop fill (ODF) method, and then the counter substrate 18 is disposed on the filling resin layer 17. Next, for example, by applying heat to the filling resin layer 17 or irradiating the filling resin layer 17 with ultraviolet rays to cure the filling resin layer 17, the substrate 11 is bonded to the counter substrate 18 via the filling resin layer 17. Therefore, the display device 10 is sealed. Note that in a case where the filling resin layer 17 contains both a thermosetting resin and an ultraviolet curable resin, the filling resin layer 17 may be irradiated with ultraviolet rays to be temporarily cured, and then heat may be applied to the filling resin layer 17 to finally cure the filling resin layer 17. The display device 10 illustrated in FIGS. 1 and 2 is obtained in the above-described manner.

### [1.3 Action and Effect]

As described above, the display device 10 according to the first embodiment includes the auxiliary electrode 19 connected to the second electrode 13C in the peripheral region R2. The auxiliary electrode 19 includes the first auxiliary electrode 19A and the second auxiliary electrode 19B disposed between the first auxiliary electrode 19A and the second electrode 13C. The second auxiliary electrode 19B contains at least one of an alkaline earth metal element and a lanthanoid element. Therefore, connectivity between the first auxiliary electrode 19A and the second electrode 13C can be improved. That is, an increase in contact resistance between the auxiliary electrode 19 and the second electrode 13C can be suppressed, and a drive voltage of the display device 10 can be reduced. Furthermore, since generation of Joule heat can be suppressed, the lifetime of the display device 10 can be extended.

When the second electrode 13C made of IZO or the like is directly formed on the first auxiliary electrode 19A made of Al or the like, a surface of the first auxiliary electrode 19A is oxidized by oxygen during film formation, and contact resistance with the second electrode 13C may increase. Furthermore, even by high temperature storage or Joule heat, oxidation of the surface of the first auxiliary electrode 19A may proceed to increase the drive voltage.

On the other hand, in the first embodiment, since the second auxiliary electrode (connectivity improving layer) 19B for suppressing damage due to processing is formed on the surface of the first auxiliary electrode 19A, it is possible to suppress an influence of oxidation of the surface of the first auxiliary electrode 19A. Therefore, an increase in contact resistance with the second electrode 13C can be suppressed. Furthermore, it is possible to suppress progress of oxidation of the surface of the first auxiliary electrode 19A by high temperature storage or Joule heat. That is, an increase in drive voltage can be suppressed.

### 2 Second Embodiment

### [2.1 Configuration of Display Device]

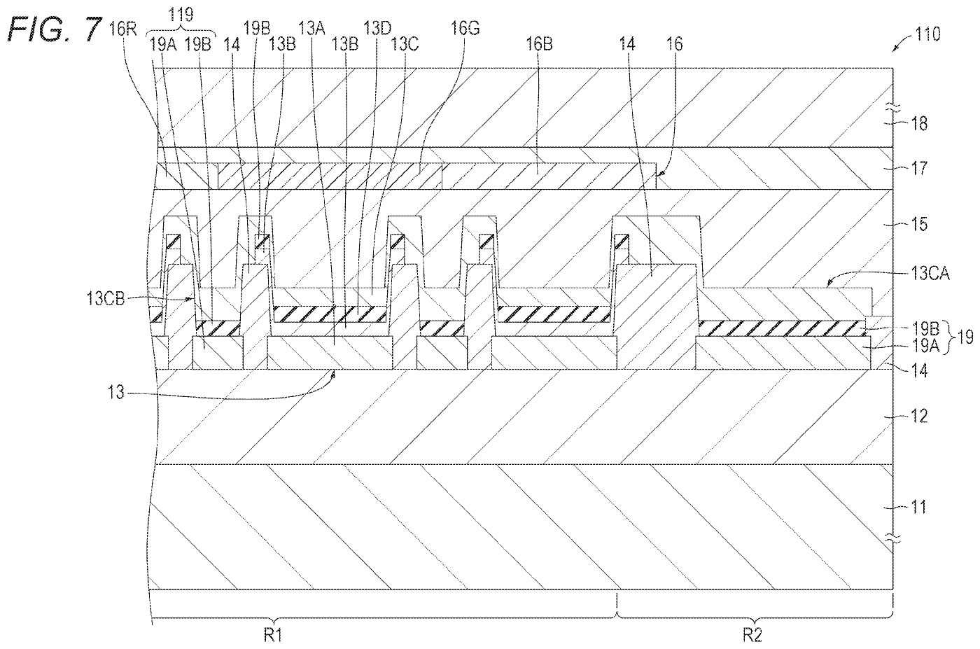

FIG. 7 is a cross-sectional view illustrating an example of a configuration of a display device 110 according to a second embodiment of the present disclosure. The display device 110 is different from the display device 10 according to the above-described first embodiment in that the display device 110 further includes a plurality of auxiliary electrodes 119 in an effective display region R1.

The auxiliary electrode 119 is an example of an inter-pixel auxiliary electrode, and is disposed between adjacent subpixels, that is, between adjacent light emitting elements 13. The auxiliary electrode 119 has the same configuration as the auxiliary electrode 19.

A second electrode 12C is connected to the auxiliary electrode 119. More specifically, the second electrode 13C has a plurality of connection portions 13CB in the effective display region R1, and each of the connection portions 13CB is connected to the auxiliary electrode 119.

The light emitting element 13 may further include an auxiliary electrode (third auxiliary electrode) 13D. The auxiliary electrode 13D is disposed between an organic layer 13B and the second electrode 13C. The auxiliary electrode 13D has a function as a transparent cathode. That is, the auxiliary electrode 119 has an electron injection property with respect to the organic layer 13B. Here, the transparent cathode also includes a semi-transparent cathode. The auxiliary electrodes 13D are disposed separately from each other for each subpixel by the insulating layer 14. The auxiliary electrode 13D is preferably made of a material having a small work function. The auxiliary electrode 13D may have the same configuration as a second auxiliary electrode 19B. That is, the auxiliary electrode 13D may contain at least one of an alkaline earth metal element and a lanthanoid element.

The alkaline earth metal and the lanthanoid are materials that can be formed into a film at a relatively low temperature among metals (for example, materials that can be formed into a film by low temperature vapor deposition). Therefore, by using at least one of an alkaline earth metal element and a lanthanoid element as a film forming material of the auxiliary electrode 13D, thermal damage to the organic layer 13B at the time of film formation can be suppressed. An example of a vapor deposition temperature of the alkaline earth metal is as follows. Mg: 443° C., Ca: 605° C., Sr: 579° C., and Ba: 629° C. On the other hand, a vapor deposition temperature of a general metal is in a range of 1000 to 2000° C.

The organic layer 13B and the auxiliary electrode 13D may be disposed on the insulating layer 14 disposed between the light emitting element 13 and the auxiliary electrode 119. In this case, the auxiliary electrode 13D may be disposed on the organic layer 13B.

### [2.2 Action and Effect]

As described above, the display device 110 according to the second embodiment includes the plurality of auxiliary electrodes 119 connected to the second electrode 13C in the effective display region R1. The auxiliary electrode 119 has the same configuration as the auxiliary electrode 19 in the first embodiment. Therefore, since an increase in contact resistance between the auxiliary electrode 119 and the second electrode 13C can be suppressed, a drive voltage of the display device 10 can be reduced. Furthermore, since generation of Joule heat can be suppressed, the lifetime of the display device 110 can be extended.

### 3 Modification Example

### Modification Example 1

In the above-described first and second embodiments, the example has been described in which the auxiliary electrode 19 has a closed loop shape so as to surround a peripheral edge of the effective display region R1. However, the auxiliary electrode 19 may be disposed on a part of the peripheral edge of the effective display region R1, or may be disposed intermittently on the peripheral edge of the effective display region R1.

### Modification Example 2

In the above-described second embodiment, the example has been described in which the display device 110 includes the plurality of auxiliary electrodes 119 in the effective display region R1 and includes the auxiliary electrodes 19 in the peripheral region R2, but the display device 110 may include only the plurality of auxiliary electrodes 119.

### Modification Example 3

In the above-described first and second embodiments, each of the display devices 10 and 110 may include a resonator structure that resonates light generated in the light emitting layer 133 for each subpixel.

### 4. Application Example

### (Electronic Apparatus)

The above-described display device 10 according to the first embodiment, the above-described display device 110 according to the second embodiment, and modification examples thereof (hereinafter, referred to as “display device 10 and the like”) may be included in various electronic apparatuses. In particular, the display device 10 and the like are preferably included in an apparatus that requires high resolution and is used by enlarging a subject near eyes, such as an electronic viewfinder of a video camera or a single-lens reflex camera or a head-mounted display.

### Specific Example 1

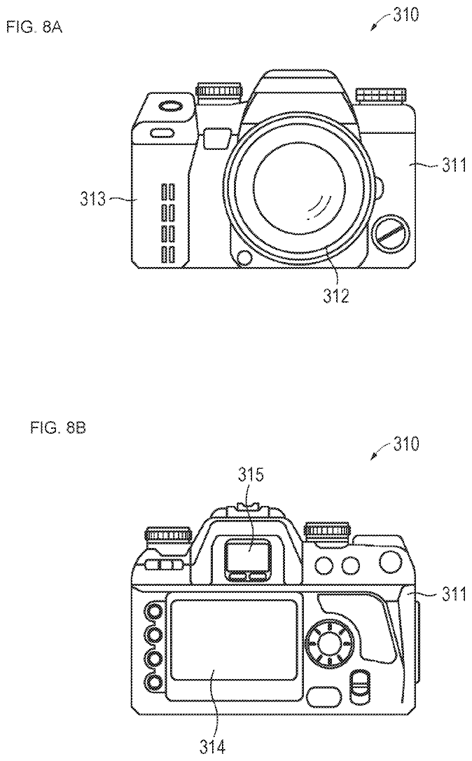

FIGS. 8A and 8B illustrate an example of an external appearance of a digital still camera 310. This digital still camera 310 is a lens interchangeable single lens reflex type camera, and has an interchangeable imaging lens unit (interchangeable lens) 312 substantially at the center in front of a camera body 311, and has a grip portion 313 to be held by an imaging person on the front left side.

A monitor 314 is disposed at a position shifted to the left from the center of a back surface of the camera body 311. An electronic viewfinder (eyepiece window) 315 is disposed above the monitor 314. By looking through the electronic viewfinder 315, an imaging person can visually recognize a light image of a subject guided from the imaging lens unit 312 and determine a composition. As the electronic viewfinder 315, any of the display device 10 and the like can be used.

### Specific Example 2

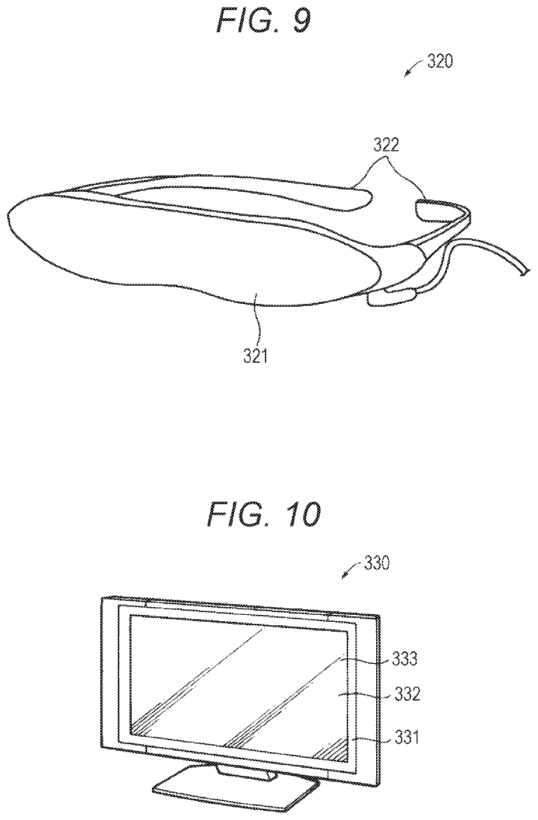

FIG. 9 illustrates an example of an external appearance of a head mounted display 320. The head mounted display 320 includes, for example, ear hooking portions 322 to be mounted on the head of a user on both sides of an eyeglass-shaped display unit 321. As the display unit 321, any of the display device 10 and the like can be used.

### Specific Example 3

FIG. 10 illustrates an example of an external appearance of a television apparatus 330. This television apparatus 330 includes, for example, a video display screen unit 331 including a front panel 332 and a filter glass 333, and the video display screen unit 331 is constituted by any of the display device 10 and the like.

### EXAMPLES

Hereinafter, the present disclosure will be described specifically with Examples, but the present disclosure is not limited to these Examples.

### Example 1

A display device having the configuration illustrated in FIGS. 1 and 2 was prepared. Materials, film thicknesses, and film forming methods of the first auxiliary electrode, the second auxiliary electrode, and the second electrode are described below.

First auxiliary electrode: Al, 200 nm, sputtering method

Second auxiliary electrode: MgAg alloy, 5 nm, vapor deposition method

Second electrode: IZO, 100 nm, sputtering method

### Example 2

A display device was prepared in a similar manner to Example 1 except that Ca was used as the material of the second auxiliary electrode.

### Comparative Example 1

A display device was prepared in a similar manner to Example 1 except that the second auxiliary electrode was not formed and the second electrode was formed directly on the first auxiliary electrode.

### (Initial Drive Voltage)

Initial drive voltages of the display devices in above-described Examples 1 and 2 and Comparative Example 1 were measured.

(Drive Voltage after High Temperature Storage)

The display devices in the above-described Examples 1 and 2 and Comparative Example 1 were stored in a high temperature environment of 85° C. and 85% RH for 500 hours, and then drive voltages of the display devices were measured.

Table 2 illustrates evaluation results of the display devices in Examples 1 and 2 and Comparative Example 1.

TABLE 2

| | | | Drive voltage |
|---|---|---|---|
| | Material | Initial | after high |
| | of second | drive | temperature |
| | auxiliary | voltage | storage |
| | electrode | [V] | [V] |
| Example 1 | Mg + Ag | 11.6 | 11.8 |
| Example 2 | Ca | 11.6 | 11.6 |
| Comparative | None | 12.3 | 12.5 |
| Example 1 | | | |

Table 2 indicates the following.

In the display device in which the second auxiliary electrode made of an alkaline earth metal is formed (Examples 1 and 2), the initial drive voltage and the drive voltage after high temperature protection can be reduced as compared with the display device in which the second auxiliary electrode is not formed (Comparative Example 1).

In the display device in which the second auxiliary electrode is made of an MgAg alloy (Example 1), the drive voltage after high temperature storage increases by 0.2 V with respect to the initial drive voltage. This is considered to be due to the following reason. Since the MgAg alloy is relatively stable and has low reactivity with oxygen, a reaction between oxygen incorporated into the second auxiliary electrode and the MgAg alloy does not proceed much at the time point after film formation. When the display device is stored at a high temperature, the reaction between oxygen and the MgAg alloy proceeds, and therefore the drive voltage increases.

On the other hand, in the display device in which the second auxiliary electrode is made of Ca (Example 2), the drive voltage after high temperature storage is similar to the initial drive voltage. This is considered to be due to the following reason. Since Ca has high reactivity with oxygen, a reaction between Ca and oxygen is almost completed at the time point after film formation. Therefore, even when the display device is stored at a high temperature, the reaction between Ca and oxygen hardly proceeds, and therefore the drive voltage does not increase.

Hereinabove, the first and second embodiments of the present disclosure and Modifications Examples thereof have been described specifically. However, the present disclosure is not limited to the above-described first and second embodiments and Modifications Examples thereof, but various modifications based on the technical idea of the present disclosure can be made.

For example, the configurations, the methods, the steps, the shapes, the materials, the numerical values, and the like exemplified in the above-described first and second embodiments and Modifications Examples thereof are only examples, and a configuration, a method, a step, a shape, a material, a numerical value, and the like different therefrom may be used as necessary.

The configurations, the methods, the steps, the shapes, the materials, the numerical values, and the like in the above-described first and second embodiments and Modifications Examples thereof can be combined to each other as long as not departing from the gist of the present disclosure.

The materials exemplified in the above-described first and second embodiments and Modifications Examples thereof can be used singly or in combination of two or more thereof unless otherwise specified.

Furthermore, the present disclosure can adopt the following configurations.

(1)

A display device including:

a first electrode;

a second electrode;

a light emitting layer disposed between the first electrode and the second electrode; and

an auxiliary electrode connected to the second electrode, in which

the auxiliary electrode includes:

a first auxiliary electrode; and

a second auxiliary electrode disposed between the first auxiliary electrode and the second electrode, and

the second auxiliary electrode contains at least one of an alkaline earth metal element and a lanthanoid element.

(2)

The display device according to (1), in which the first auxiliary electrode is constituted by at least one of a metal layer and a metal oxide layer.

(3)

The display device according to (1) or (2), further including an insulating layer between the first auxiliary electrode and the second auxiliary electrode.

(4)

The display device according to (3), in which the auxiliary electrode is capable of injecting electrons from the first auxiliary electrode to the second auxiliary electrode via the insulating layer.

(5)

The display device according to any one of (1) to (4), in which the auxiliary electrode is disposed in a peripheral edge portion of a display region.

(6)

The display device according to any one of (1) to (4), in which a plurality of the auxiliary electrodes is disposed in a display region.

(7)

The display device according to any one of (1) to (4), further including a plurality of inter-pixel auxiliary electrodes disposed between subpixels in a display region, in which

each of the plurality of inter-pixel auxiliary electrodes is connected to the second electrode, and

each of the plurality of inter-pixel auxiliary electrodes has the same configuration as the auxiliary electrode.

(8)

The display device according to any one of (1) to (6), further including a third auxiliary electrode disposed between the light emitting layer and the second electrode,

in which the third auxiliary electrode has the same configuration as the second auxiliary electrode.

(9)

The display device according to (8), in which the third auxiliary electrode has an electron injection property.

(10)

The display device according to any one of (1) to (9), in which the second auxiliary electrode has a smaller work function than the first auxiliary electrode.

(11)

The display device according to any one of (1) to (10), in which the second electrode is constituted by at least one of a metal layer and a metal oxide layer.

(12)

The display device according to any one of (1) to (11), in which

the first electrode is an anode, and

the second electrode is a cathode.

(13)

The display device according to any one of (1) to (12), in which the light emitting layer contains an organic light emitting material.

(14)

An electronic apparatus including the display device according to any one of (1) to (13).

### REFERENCE SIGNS LIST

10 Display device
11 Substrate
11A Pad portion
12 Insulating layer
13 Light emitting element
13A First electrode
13B Organic layer
13C Second electrode
13CA Peripheral edge portion
13CB Connection portion
13D Auxiliary electrode (third auxiliary electrode)
14 Insulating layer
15 Protective layer
16 Color filter
16R Red filter
16G Green filter
16B Blue filter
17 Filling resin layer
18 Counter substrate
19 Auxiliary electrode
19A First auxiliary electrode
19B Second auxiliary electrode
110 Display device
119 Auxiliary electrode (inter-pixel auxiliary
electrode)
131 Hole injection layer
132 Hole transport layer
133 Organic light emitting layer
134 Electron transport layer
310 Digital still camera (electronic apparatus)
320 Head mounted display (electronic apparatus)
330 Television apparatus (electronic apparatus)
R1 Effective display region
R2 Peripheral region

1. A display device comprising:
a first electrode;
a second electrode;
a light emitting layer disposed between the first electrode and the second electrode; and
an auxiliary electrode connected to the second electrode, wherein
the auxiliary electrode includes:
a first auxiliary electrode; and
a second auxiliary electrode disposed between the first auxiliary electrode and the second electrode, and
the second auxiliary electrode contains at least one of an alkaline earth metal element and a lanthanoid element.

2. The display device according to claim 1, wherein the first auxiliary electrode is constituted by at least one of a metal layer and a metal oxide layer.

3. The display device according to claim 1, further comprising an insulating layer between the first auxiliary electrode and the second auxiliary electrode.

4. The display device according to claim 3, wherein the auxiliary electrode is capable of injecting electrons from the first auxiliary electrode to the second auxiliary electrode via the insulating layer.

5. The display device according to claim 1, wherein the auxiliary electrode is disposed in a peripheral edge portion of a display region.

6. The display device according to claim 1, wherein a plurality of the auxiliary electrodes is disposed in a display region.

7. The display device according to claim 1, further comprising a plurality of inter-pixel auxiliary electrodes disposed between subpixels in a display region, wherein
each of the plurality of inter-pixel auxiliary electrodes is connected to the second electrode, and
each of the inter-pixel auxiliary electrodes has the same configuration as the auxiliary electrode.

8. The display device according to claim 6, further comprising a third auxiliary electrode disposed between the light emitting layer and the second electrode,
wherein the third auxiliary electrode has the same configuration as the second auxiliary electrode.

9. The display device according to claim 8, wherein the third auxiliary electrode has an electron injection property.

10. The display device according to claim 1, wherein the second auxiliary electrode has a smaller work function than the work function of the first auxiliary electrode.

11. The display device according to claim 1, wherein the second electrode is constituted by at least one of a metal layer and a metal oxide layer.

12. The display device according to claim 1, wherein
the first electrode is an anode, and
the second electrode is a cathode.

13. The display device according to claim 1, wherein the light emitting layer contains an organic light emitting material.

14. An electronic apparatus comprising the display device according to claim 1.
